(19) United States
(12) Patent Application Publication
(10) Pub. No.: US 2024/0039478 A1
(43) Pub. Date: Feb. 1, 2024

(54) CIRCUIT WITH A PSEUDO CLASS-AB STRUCTURE

(71) Applicant: MEDIATEK INC., Hsinchu City (TW)

(72) Inventors: Chih-Hou TSAI, Hsinchu City (TW); Zhao-Hui LIN, Hsinchu City (TW); Ting-Yu KO, Hsinchu City (TW); Shu-Lin CHANG, Hsinchu City (TW); Chien-Yuan CHENG, Hsinchu City (TW); Shao-Yung LU, Hsinchu City (TW)

(21) Appl. No.: 18/298,425

(22) Filed: Apr. 11, 2023

Related U.S. Application Data
(60) Provisional application No. 63/386,688, filed on Dec. 9, 2022.
(60) Provisional application No. 63/369,667, filed on Jul. 28, 2022.

(51) Int. Cl. H03F 1/02; H03F 3/16; H03F 1/42

(52) U.S. Cl. CPC H03F 1/0205; H03F 3/16; H03F 1/42; H03F 2200/36

(57) ABSTRACT

A circuit with a pseudo class-AB structure is shown. The circuit has an output stage, a first capacitor, and a first impedance component. The output stage has a first PMOS (p-type Metal-Oxide-Semiconductor Field-Effect Transistor) and a first NMOS (n-type MOSFET). The first connection node between the drain terminal of the first PMOS and the drain terminal of the first NMOS is coupled to the first output terminal of the circuit. The first capacitor is coupled between the gate terminal of the first PMOS and the gate terminal of the first NMOS. The first impedance component is coupled in parallel with the first capacitor between the gate terminal of the first PMOS and the gate terminal of the first NMOS.

### CROSS REFERENCE TO RELATED APPLICATIONS

This application claims the benefit of U.S. Provisional Application No. 63/369,667, filed Jul. 28, 2022, and U.S. Provisional Application No. 63/386,688, filed Dec. 9, 2022, the entirety of which are incorporated by reference herein.

### BACKGROUND OF THE INVENTION

### Field of the Invention

The present invention relates to the output stage design of a circuit.

### Description of the Related Art

In high drive current applications, the input and output linearity is a design bottleneck. The circuit bandwidth, power consumption, and circuit size should all be taken into consideration.

A class-A structure with good linearity has poor power efficiency. A class-B structure with good power efficiency has poor linearity.

A class-AB structure that has acceptable performance in both linearity and power efficiency may suffer from insufficient headroom.

### BRIEF SUMMARY OF THE INVENTION

A circuit with sufficient headroom that performs well in terms of linearity and power efficiency is shown.

A circuit in accordance with an exemplary embodiment of the present invention has an output stage, a first capacitor, and a first impedance component. The output stage has a first PMOS (p-type Metal-Oxide-Semiconductor Field-Effect Transistor) and a first NMOS (n-type Metal-Oxide-Semiconductor Field-Effect Transistor). The first connection node between the drain terminal of the first PMOS and the drain terminal of the first NMOS is coupled to the first output terminal of the circuit. The first capacitor is coupled between the gate terminal of the first PMOS and the gate terminal of the first NMOS. The first impedance component is coupled in parallel with the first capacitor between the gate terminal of the first PMOS and the gate terminal of the first NMOS. Such a pseudo class-AB structure results in good performance with low-frequency signals.

In an exemplary embodiment, the circuit has a bias circuit. The bias circuit generates a first bias current to be mirrored to bias the first impedance component. The bias circuit comprises a replicated impedance component corresponding to the first impedance component. The first end and a second end of the replicated impedance component are biased at the first voltage and the second voltage, respectively, to determine the first bias current.

In an exemplary embodiment, the first voltage is lower than the second voltage for a low-voltage design.

In an exemplary embodiment, the circuit is in a differential form, such as implementing a differential amplifier.

In another exemplary embodiment, the circuit is in a single end form, such as implementing a low-dropout regulator.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 depicts a circuit 100 with a pseudo class-AB structure;

FIG. 2A depicts a bias circuit 200 for the low voltage applications;

FIG. 2B depicts how the bias circuit 200 is coupled to the differential amplifier;

FIG. 3A depicts an LDO 300; and

FIG. 3B depicts a bias circuit 302 for the LDO 300.

### DETAILED DESCRIPTION OF THE INVENTION

The following description is made for the purpose of illustrating the general principles of the invention and should not be taken in a limiting sense. The scope of the invention is best determined by reference to the appended claims.

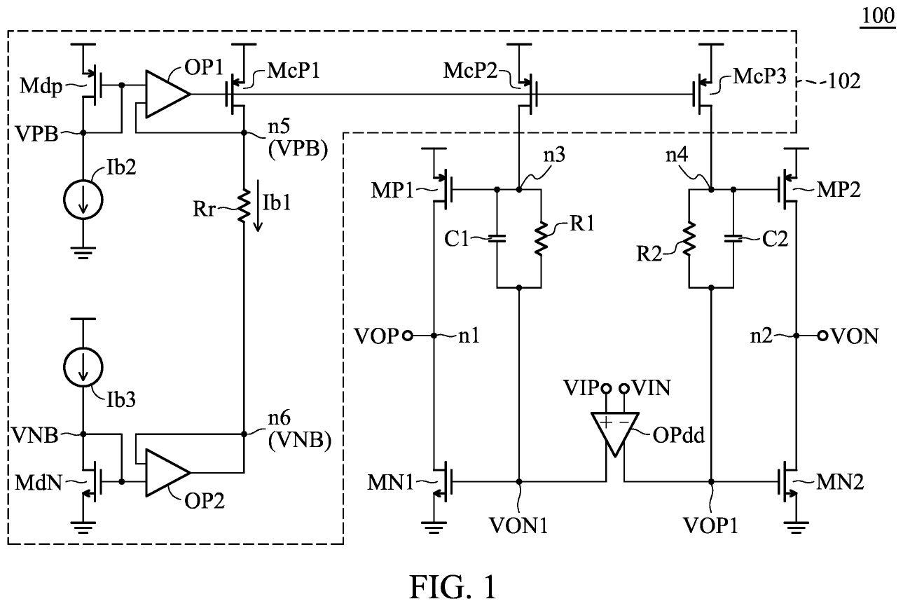

FIG. 1 depicts a circuit 100 with a pseudo class-AB structure. The circuit 100 is implemented as a differential amplifier. The output stage of the circuit 100 has a first PMOS (p-type Metal-Oxide-Semiconductor Field-Effect Transistor) MP1, a first NMOS (n-type MOSFET) MN1, a second PMOS MP2, and a second NMOS MN2. The first connection node n1 between the drain terminal of the first PMOS MP1 and the drain terminal of the first NMOS MN1 is coupled to the first output terminal (VOP) of the circuit 100, which is a positive differential output terminal of the differential amplifier. The second connection node n2 between the drain terminal of the second PMOS MP2 and the drain terminal of the second NMOS MN2 is coupled to the second output terminal (VON) of the circuit 100, which is a negative differential output terminal of the differential amplifier. The first capacitor C1 is coupled between the gate terminal (n3) of the first PMOS MP1 and the gate terminal of the first NMOS MN1. The second capacitor C2 is coupled between the gate terminal (n4) of the second PMOS MP2 and the gate terminal of the second NMOS MN2. In particular, the first impedance component R1 is coupled in parallel with the first capacitor C1 between the gate terminal of the first PMOS MP1 and the gate terminal of the first NMOS MN1, and the second impedance component R2 is coupled in parallel with the second capacitor C2 between the gate terminal of the second PMOS MP2 and the gate terminal of the second NMOS MN2. With the parallel connected capacitor and impedance component (C1//R1 & C2//R2), the output stage is in a class-AB structure.

In an old design without the impedance components R1 and R2, the transconductance Gm of the output stage may be degraded at low frequencies (degraded from (gmₚ+gmₙ) to gmₙ) in high current driving applications (e.g., Wi-Fi 7). Thus, more output stage current is required, and the power consumption and circuit complexity is increased. The proposed pseudo class-AB structure, however, solves these problems.

Even in cases where there is a large load, the impedance components R1 and R2 track the low-frequency signals to maintain the transconductance Gm of the output stage at a high level (gmₙ+gmₚ rather than gmₙ) while the high-frequency signals are dealt with by the capacitors C1 and C2. The parallel connected capacitor and impedance component (C1//R1 & C2//R2) provide all-pass signal paths.

In some other exemplary embodiments, the impedance components R1 and R2 are replaced by triode region MOSs, switched capacitor resistors, and so on.

In FIG. 1, the input stage of the differential amplifier uses a differential-in-and-differential-out operational amplifier OPdd to receive a differential input. The differential-in-and-differential-out operational amplifier OPdd has a positive input terminal ‘+’ receiving a positive signal VIP of the differential input, a negative input terminal ‘−’ receiving a negative signal VIN of the differential input, a positive output terminal (VOP1) coupled to the gate terminal of the second NMOS MN2, and a negative output terminal (VON1) coupled to the gate terminal of the first NMOS MN1. With the parallel connected capacitor and impedance component (C1//R1 & C2//R2), the DC swing and the intermodulation distortion (IM3) of the differential amplifier all are improved in the low frequency region.

FIG. 1 further shows a bias circuit 102 for the differential amplifier. The bias circuit 102 generates a first bias current Ib1 to be mirrored to bias the first impedance component R1, and is also mirrored to bias the second impedance component R2. The bias circuit 102 comprises a replicated impedance component Rr corresponding to the first impedance component (R1/R2). The first end (n5) and second end (n6) of the replicated impedance component are biased at the first voltage VPB and the second voltage VNB, respectively, to determine the first bias current Ib1. In this manner, the first and second impedance components R1 and R2 are well biased. In the output stage, the properly biased complementary MOS gates keep the advantages (power efficiency) of its class-AB structure.

As shown, the bias circuit 102 further has a diode-connected PMOS MdP, a first operational amplifier OP1, and a first current PMOS McP1. The diode-connected PMOS MdP has a source terminal coupled to a power line. The drain terminal and the gate terminal of the diode-connected PMOS MdP are connected together, and the diode-connected PMOS MdP is biased by a second bias current Ib2. The first operational amplifier OP1 has a first input terminal coupled to the gate terminal of the diode-connected PMOS MdP, a second input terminal coupled to the first end (n5) of the replicated impedance component Rr, and an output terminal. The first current PMOS McP1 has a gate terminal coupled to the output terminal of the first operational amplifier OP1, a source terminal coupled to the power line, and a drain terminal coupled to the first end (n5) of the replicated impedance component Rr.

The bias circuit 102 further has a diode-connected NMOS MdN and a second operational amplifier OP2. The diode-connected NMOS MdN has a source terminal coupled to ground. The drain terminal and the gate terminal of the diode-connected NMOS MdN are connected to each other, and the diode-connected NMOS MdN is biased by the third bias current Ib3. The second operational amplifier OP2 has a first input terminal coupled to the gate terminal of the diode-connected NMOS MdN, a second input terminal coupled to the second end (n6) of the replicated impedance component Rr, and an output terminal also connected to the second end (n6) of the replicated impedance component Rr.

In such a design, the first end (n5) of the replicated impedance component Rr is regulated at the first voltage VPB, and the second end (n6) of the replicated impedance component Rr is regulated at the first voltage VNB.

In FIG. 1, the bias circuit 102 further has a second current PMOS McP2 and a third current PMOS McP3 for mirroring the first bias current Ib1. The second current PMOS McP2 has a gate terminal coupled to the gate terminal of the first current PMOS McP1, a source terminal coupled to the power line, and a drain terminal coupled to a third connection node n3 that couples the parallel-connected first capacitor C1 and first impedance component R1 with the gate terminal of the first PMOS MP1. The third current PMOS McP3 has a gate terminal coupled to the gate terminal of the first current PMOS McP1, a source terminal coupled to the power line, and a drain terminal coupled to a fourth connection node n4 that couples the parallel-connected second capacitor C2 and second impedance component R2 with the gate terminal of the second PMOS MP2.

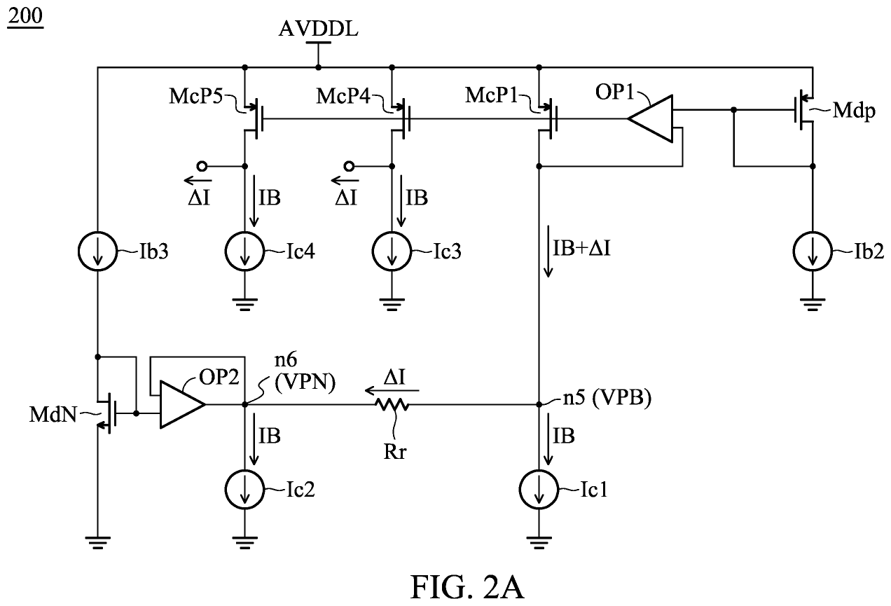

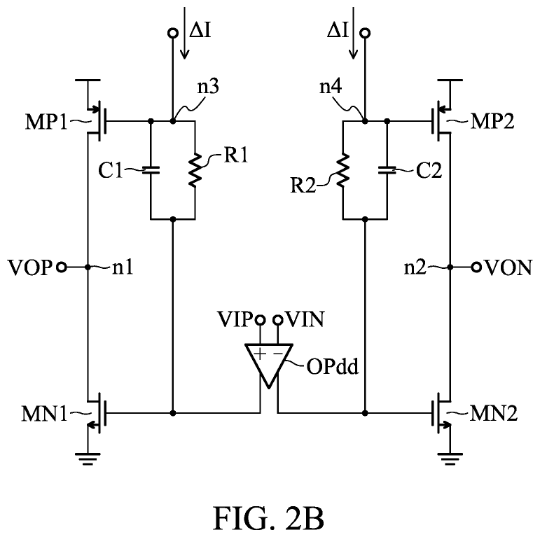

In low voltage domain, the first voltage VPB may be lower than the second voltage VNB. FIG. 2A depicts a bias circuit 200 for the low voltage applications. FIG. 2B depicts how the bias circuit 200 is coupled to the differential amplifier.

As shown in FIG. 2A, the bias circuit 200 has a first current source Ic1 and a second current source Ic2. The first current source Ic1 drains a first current from a fifth connection node n5 between the drain terminal of the first current PMOS McP1 and the first end of the replicated impedance component Rr. The second current source Ic2 drains a second current from a sixth connection node n6 between the output terminal of the second operational amplifier OP2 and the second end of the replicated impedance component Rr.

The bias circuit 200 further has a fourth current PMOS McP4 and a third current source Ic3. The fourth current PMOS McP4 has a gate terminal coupled to the gate terminal of the first current PMOS McP1, a source terminal coupled to the power line, and a drain terminal. The third current source Ic3 drains a third current from the drain terminal of the fourth current PMOS McP4. The drain terminal of the fourth current PMOS McP4 is coupled to the third connection node n3 of the differential amplifier as presented in FIG. 2B.

The bias circuit 200 further has a fifth current PMOS McP5 and a fourth current source Ic4. The fifth current PMOS McP5 has a gate terminal coupled to the gate terminal of the first current PMOS McP1, a source terminal coupled to the power line, and a drain terminal. The fourth current source Ic4 drains a fourth current from the drain terminal of the fifth current PMOS McP5. The drain terminal of the fifth current PMOS McP5 is coupled to the fourth connection node n4 of the differential amplifier as presented in FIG. 2B.

In FIG. 2A, the first current source Ic1, the second current source Ic2, the third current source Ic3, and the fourth current source Ic4 are of the same current value IB. Thus, no matter the first voltage VPB is greater or lower than the second voltage VNB, the current ΔI flowing through the replicated impedance component Rr is successfully mirrored to the first impedance component R1 and the second impedance component R2.

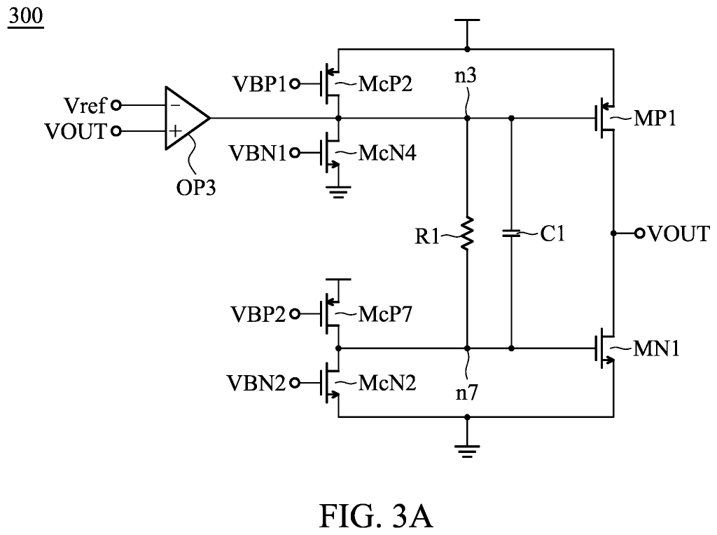

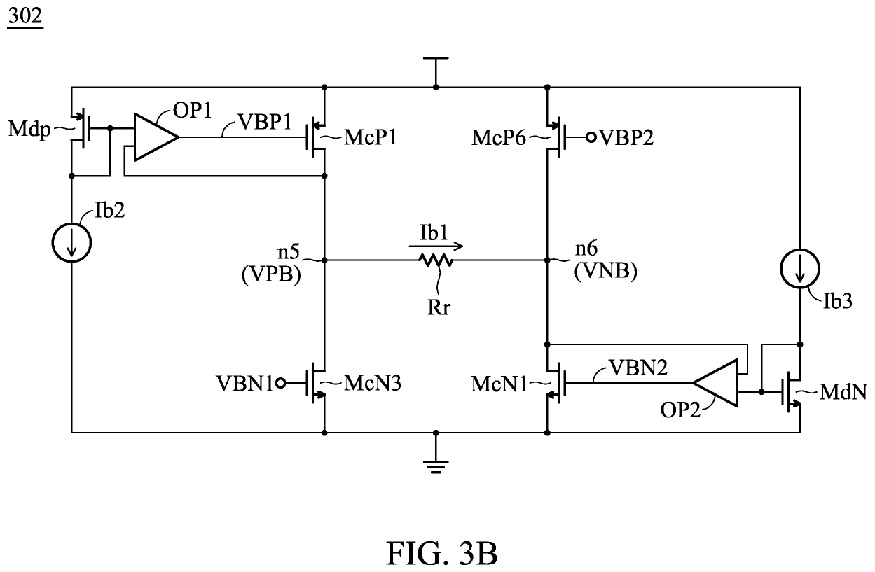

The pseudo class-AB structure may be used in a single-end circuit, such as a low dropout regulator (LDO). FIG. 3A depicts an LDO 300, and FIG. 3B depicts a bias circuit 302 for the LDO 300.

The LDO 300 includes a class-AB structure (formed by MP1, MN1, C1, and R1) and a third operational amplifier OP3. The third operational amplifier OP3 has a positive input terminal ‘+’ for feedback of the LDO voltage VOUT, a negative input terminal ‘−’ biased at a reference voltage Vref, and an output terminal coupled to the gate terminal of the first PMOS MP1.

In comparison with the bias circuit 200 shown in FIG. 2A, the bias circuit 302 further has a first current NMOS McN1, having a gate terminal coupled to the output terminal of the second operational amplifier OP2, a source terminal coupled to the ground, and a drain terminal coupled to the second end (n6) of the replicated impedance component Rr, and an output terminal.

For mirroring the first bias current Ib1 (flowing through the replicated impedance component Rr) to the first impedance component R1 of the LDO 300, the LDO 300 of FIG. 3A further has a second current PMOS McP2 and a second current NMOS McN2. The second current PMOS McP2 has a gate terminal coupled to the gate terminal of the first current PMOS McP1 of FIG. 3B (biased at VBP1), a source terminal coupled to the power line, and a drain terminal coupled to the third connection node n3. The second current NMOS McN2 has a gate terminal coupled to the gate terminal of the first current NMOS McN1 of FIG. 3B (biased at VBN2), a source terminal coupled to the ground, and a drain terminal coupled to a seventh connection node n7 that couples the parallel-connected first capacitor C1 and first impedance component R1 with the gate terminal of the first NMOS MN1.

Especially, for low voltage applications, the bias circuit 302 of FIG. 3B further has a sixth current PMOS McP6 and a third current NMOS McN3. The sixth current PMOS McP6 has a source terminal coupled to the power line, a drain terminal coupled to the second end (n6) of the replicated impedance component Rr, and a gate terminal. The third current NMOS McN3 has a source terminal coupled to the ground, a drain terminal coupled to the first end (n5) of the replicated impedance component Rr, and a gate terminal. Correspondingly, the LDO 300 of FIG. 3A has a seventh current PMOS McP7 and a fourth current NMOS Mcn4. The seventh current PMOS McP7 has a source terminal coupled to the power line, a drain terminal coupled to the seventh connection node n7, and a gate terminal coupled to the gate terminal of the sixth current PMOS McP6 of FIG. 3B (biased at VBP2). The fourth current NMOS McN4 has a source terminal coupled to the ground, a drain terminal coupled to the third connection node n3, and a gate terminal coupled to the gate terminal of the third current NMOS McN3 of FIG. 3B (biased at VBN1). In an exemplary embodiment, VBP2 and VBN1 are biased for generation of the same current values.

Any circuit with the proposed pseudo class-AB structure (have the parallel-connected capacitor and impedance component between the gates of the complementary MOS gates) should be considered within the scope of the present invention.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A circuit with a pseudo class-AB structure, comprising:
an output stage, having a first PMOS and a first NMOS, wherein a first connection node between a drain terminal of the first PMOS and a drain terminal of the first NMOS is coupled to a first output terminal of the circuit;
a first capacitor, coupled between a gate terminal of the first PMOS and a gate terminal of the first NMOS; and
a first impedance component, coupled in parallel with the first capacitor between the gate terminal of the first PMOS and the gate terminal of the first NMOS.

2. The circuit as claimed in claim 1, further comprising:
a bias circuit, generating a first bias current to be mirrored to bias the first impedance component,
wherein:
the bias circuit comprises a replicated impedance component corresponding to the first impedance component; and
a first end and a second end of the replicated impedance component are biased at a first voltage and a second voltage, respectively, to determine the first bias current.

3. The circuit as claimed in claim 1, further comprising:
a second capacitor; and
a second impedance component;
wherein:
the circuit is implemented as a differential amplifier;
the output stage further has a second PMOS and a second NMOS, wherein a second connection node between a drain terminal of the second PMOS and a drain terminal of the second NMOS is coupled to a second output terminal of the circuit;
the second capacitor and the second impedance component are coupled in parallel between a gate terminal of the second PMOS and a gate terminal of the second NMOS;
the first output terminal of the circuit is a positive differential output terminal; and
the second output terminal of the circuit is a negative differential output terminal.

4. The circuit as claimed in claim 3, further comprising:
a bias circuit, generating a first bias current to be mirrored to bias the first impedance component, and further mirrored to bias the second impedance component,
wherein:
the bias circuit comprises a replicated impedance component corresponding to the first impedance component, and the replicated impedance component also corresponds to the second impedance component; and
a first end and a second end of the replicated impedance component are biased at a first voltage and a second voltage, respectively, to determine the first bias current.

5. The circuit as claimed in claim 4, further comprising:
an input stage, receiving a differential input,
wherein the input stage is coupled to the output stage through the gate terminal of the first NMOS and the gate terminal of the second NMOS.

6. The circuit as claimed in claim 5, wherein:
the input stage includes a differential-in-and-differential-out operational amplifier, having a positive input terminal receiving a positive signal of the differential input, a negative input terminal receiving a negative signal of the differential input, a positive output terminal coupled to the gate terminal of the second NMOS, and a negative output terminal coupled to the gate terminal of the first NMOS.

7. The circuit as claimed in claim 5, wherein the bias circuit further comprises:
a diode-connected PMOS, having a source terminal coupled to a power line, wherein a drain terminal and a gate terminal of the diode-connected PMOS are connected together, and the diode-connected PMOS is biased by a second bias current;
a first operational amplifier, having a first input terminal coupled to the gate terminal of the diode-connected PMOS, a second input terminal coupled to the first end of the replicated impedance component, and an output terminal; and
a first current PMOS, having a gate terminal coupled to the output terminal of the first operational amplifier, a source terminal coupled to the power line, and a drain terminal coupled to the first end of the replicated impedance component.

8. The circuit as claimed in claim 7, wherein the bias circuit further comprises:
a diode-connected NMOS, having a source terminal coupled to ground, wherein a drain terminal and a gate terminal of the diode-connected NMOS are connected with each other, and the diode-connected NMOS is biased by a third bias current; and
a second operational amplifier, having a first input terminal coupled to the gate terminal of the diode-connected NMOS, a second input terminal coupled to the second end of the replicated impedance component, and an output terminal also connected to the second end of the replicated impedance component.

9. The circuit as claimed in claim 7, the bias circuit further comprising:
a second current PMOS, having a gate terminal coupled to the gate terminal of the first current PMOS, a source terminal coupled to the power line, and a drain terminal coupled to a third connection node that couples the parallel-connected first capacitor and first impedance component with the gate terminal of the first PMOS; and
a third current PMOS, having a gate terminal coupled to the gate terminal of the first current PMOS, a source terminal coupled to the power line, and a drain terminal coupled to a fourth connection node that couples the parallel-connected second capacitor and second impedance component with the gate terminal of the second PMOS.

10. The circuit as claimed in claim 8, wherein the bias circuit further comprises:
a first current source, draining a first current from a fifth connection node between the drain terminal of the first current PMOS and the first end of the replicated impedance component; and
a second current source, draining a second current from a sixth connection node between the output terminal of the second operational amplifier and the second end of the replicated impedance component.

11. The circuit as claimed in claim 10, wherein the bias circuit further comprises:
a fourth current PMOS, having a gate terminal coupled to the gate terminal of the first current PMOS, a source terminal coupled to the power line, and a drain terminal; and
a third current source, draining a third current from the drain terminal of the fourth current PMOS;
wherein the drain terminal of the fourth current PMOS is coupled to a third connection node that couples the parallel-connected first capacitor and first impedance component with the gate terminal of the first PMOS.

12. The circuit as claimed in claim 11, wherein the bias circuit further comprises:
a fifth current PMOS, having a gate terminal coupled to the gate terminal of the first current PMOS, a source terminal coupled to the power line, and a drain terminal; and
a fourth current source, draining a fourth current from the drain terminal of the fifth current PMOS;
wherein the drain terminal of the fifth current PMOS is coupled to a fourth connection node that couples the parallel-connected second capacitor and second impedance component with the gate terminal of the second PMOS.

13. The circuit as claimed in claim 12, wherein:
the first voltage supplied to the first end of the replicated impedance component is lower than the second voltage supplied to the second end of the replicated impedance component.

14. The circuit as claimed in claim 12, wherein:
the first current source, the second current source, the third current source, and the fourth current source are of the same current value.

15. The circuit as claimed in claim 2, further comprising:
a third operational amplifier, having a positive input terminal coupled to the first output terminal of the circuit, a negative input terminal biased at a reference voltage, and an output terminal coupled to the gate terminal of the first PMOS;
wherein the first output terminal of the circuit outputs a low-dropout voltage, and the circuit is implemented as a low-dropout regulator.

16. The circuit as claimed in claim 15, wherein the bias circuit further comprises:
a diode-connected PMOS, having a source terminal coupled to a power line, wherein a drain terminal and a gate terminal of the diode-connected PMOS are connected together, and the diode-connected PMOS is biased by a second bias current;
a first operational amplifier, having a first input terminal coupled to the gate terminal of the diode-connected PMOS, a second input terminal coupled to the first end of the replicated impedance component, and an output terminal; and
a first current PMOS, having a gate terminal coupled to the output terminal of the first operational amplifier, a source terminal coupled to the power line, and a drain terminal coupled to the first end of the replicated impedance component.

17. The circuit as claimed in claim 16, wherein the bias circuit further comprises:
a diode-connected NMOS, having a source terminal coupled to ground, wherein a drain terminal and a gate terminal of the diode-connected NMOS are connected together, and the diode-connected NMOS is biased by a third bias current;
a second operational amplifier, having a first input terminal coupled to the gate terminal of the diode-connected NMOS, a second input terminal coupled to the second end of the replicated impedance component, and an output terminal; and
a first current NMOS, having a gate terminal coupled to the output terminal of the second operational amplifier, a source terminal coupled to the ground, a drain terminal coupled to the second end of the replicated impedance component, and an output terminal.

18. The circuit as claimed in claim 17, further comprising:
a second current PMOS, having a gate terminal coupled to the gate terminal of the first current PMOS, a source terminal coupled to the power line, and a drain terminal coupled to a third connection node that couples the parallel-connected first capacitor and first impedance component with the gate terminal of the first PMOS.

19. The circuit as claimed in claim 18, further comprising:
a second current NMOS, having a gate terminal coupled to the gate terminal of the first current NMOS, a source terminal coupled to the ground, and a drain terminal coupled to a seventh connection node that couples the parallel-connected first capacitor and first impedance component with the gate terminal of the first NMOS.

20. The circuit as claimed in claim 19, wherein the bias circuit further comprises:
a sixth current PMOS, having a source terminal coupled to the power line, a drain terminal coupled to the second end of the replicated impedance component, and a gate terminal; and
a third current NMOS, having a source terminal coupled to the ground, a drain terminal coupled to the first end of the replicated impedance component, and a gate terminal.

21. The circuit as claimed in claim 20, further comprising:
a seventh current PMOS, having a source terminal coupled to the power line, a drain terminal coupled to the seventh connection node that couples the parallel-connected first capacitor and first impedance component with the gate terminal of the first NMOS, and a gate terminal coupled to the gate terminal of the sixth current PMOS; and
a fourth current NMOS, having a source terminal coupled to the ground, a drain terminal coupled to the third connection node that couples the parallel-connected first capacitor and first impedance component with the gate terminal of the first PMOS, and a gate terminal coupled to the gate terminal of the third current NMOS.

22. The circuit as claimed in claim 21, wherein:
the first voltage supplied to the first end of the replicated impedance component is lower than the second voltage supplied to the second end of the replicated impedance component.
